(19) United States
(12) Patent Application Publication
(10) Pub. No.: US 2024/0371411 A1
(43) Pub. Date: Nov. 7, 2024

(54) CONFIGURABLE MEMORY CARD CONNECTOR

(71) Applicant: Amphenol Commercial Products (Chengdu) Co., Ltd., Chengdu (CN)

(72) Inventors: Kui Yang, Chengdu (CN); Xiaodong Hu, Chengdu (CN)

(73) Assignee: Amphenol Commercial Products (Chengdu) Co., Ltd., Chengdu (CN)

(21) Appl. No.: 18/654,797

(22) Filed: May 3, 2024

(30) Foreign Application Priority Data
May 6, 2023 (CN) 202310500281.6
May 6, 2023 (CN) 202321059796.9

(51) Int. Cl. G11C 5/04; H01R 12/71; H01R 12/72; H01R 12/73; H01R 13/502; H01R 13/631; H01R 13/639; H01R 43/18

(52) U.S. Cl. CPC G11C 5/04; H01R 12/716; H01R 13/502; H01R 13/631; H01R 13/639; H01R 43/18; H01R 12/721; H01R 12/737

(57) ABSTRACT

A configurable electrical connector. The connector has a housing body, a tower extending from the housing body and beyond a mating face, and a latch movably coupled to the housing body and/or tower. The tower is configurable according to a mating component. The tower can be a tower portion formed with the housing body. The tower can include an extender, with a lower portion disposed inside the tower portion and an upper portion disposed on the tower portion. The extender has an opening through which the latch can pass for engaging a mating component at the locked position. Such a configuration enables the connector to reliably hold a card taller than a standard card (e.g., according to DDR5 or below), and therefore enable the connector to be compatible with both standard cards and tall cards so as to support different storage capacities and data rates.

### CROSS-REFERENCE TO RELATED APPLICATIONS

This application claims priority to and the benefit of Chinese Patent Application Serial No. 202321059796.9, filed on May 6, 2023. This application also claims priority to and the benefit of Chinese Patent Application Serial No. 202310500281.6, filed on May 6, 2023. The entire contents of these applications are incorporated herein by reference in their entirety.

### TECHNICAL FIELD

This application relates generally to electrical interconnection systems, such as those including electrical connectors, used to interconnect electronic assemblies.

### BACKGROUND

Electrical connectors are used in many electronic systems. It is easier and more cost effective to manufacture a system as separate electronic assemblies, such as printed circuit boards (PCBs), which may be joined together with electrical connectors. Having separable connectors enables components of the electronic system manufactured by different manufacturers to be readily assembled. Separable connectors also enable components to be readily replaced after the system is assembled, either to replace defective components or to upgrade the system with higher performance components.

Computers, for example, are often manufactured with connectors that serve as sockets for memory cards. A memory card may contain one or multiple memory chips and may be inserted into a socket to increase the available memory in the computer. Memory cards have standardized electrical and mechanical interfaces, so as do the memory sockets. Many memory cards, for example, are designed according to a DDR standard, such as DDR4 or DDR5.

### BRIEF SUMMARY

Aspects of the present disclosure relate to configurable memory card electrical connectors.

Some embodiments relate to a memory card connector. The memory card connector may include a housing comprising a body extending in a longitudinal direction and having an end, a tower portion extending from the end of the body in a vertical direction perpendicular to the longitudinal direction, and a slot extending from the body to the tower portion; and a plurality of conductive elements held in the housing, each of the plurality of conductive elements comprising a mating contact portion curving into the slot and a tail portion extending out of a mounting face of the housing, wherein the tower portion of the housing comprises a groove extending in the vertical direction and beyond the mounting face.

Optionally, the groove is a first groove disposed on a side of the slot; the tower portion of the housing comprises a second groove facing away from the slot; and the connector comprises a latch at least partially disposed in the second groove and movably coupled to the tower portion between a locked position and unlocked position.

Optionally, the latch comprises a handle disposed outside the second groove and extending outwardly from the tower portion, and a rib extending from the handle in an opposite direction; and the rib is narrower than the handle in a transverse direction perpendicular to both the longitudinal direction and the vertical direction.

Optionally, the connector comprises an extender comprising a first portion extending through the groove of the tower portion and a second portion disposed on the tower portion.

Optionally, the second portion of the extender comprises a slot aligned with a portion of the slot of the housing that extends in the tower portion.

Optionally, the extender comprises a protrusion protruding into the slot.

Optionally, the extender comprises an insulative housing; and a conductive body comprising an upper portion disposed in the extender housing and a lower portion extending out of the insulative housing and through the groove of the tower portion.

Optionally, the lower portion of the conductive body of the extender comprises a barb engaging the tower portion inside the groove.

Optionally, the lower portion of the conductive body of the extender is configured to insert into a hole of a circuit board; and the tail portions of the plurality of conductive elements are configured to surface mount to the circuit board.

Some embodiments relate to an electrical connector. The electrical connector may include a housing comprising a body having a mating face and a mounting face, and a tower extending from an end of the body and beyond the mating face of the body of the housing; and a latch movably coupled to the housing between a locked position and an unlocked position and comprising a rib configured to extend through an opening of the tower at the locked position.

Optionally, the tower comprises a tower portion extending from the end of the body; and an extender at least partially disposed on the tower portion and comprising the opening.

Optionally, the housing comprises a slot extending from the body to the tower; the tower portion of the tower comprises a groove disposed on a side of the slot; and the extender of the tower comprises a first portion extending through the groove and a second portion disposed on the groove.

Optionally, the second portion of the extender comprises a first sidewall and a second sidewall on opposite sides of the slot, first protrusions extending from the first sidewall into the slot, and second protrusions extending from the second sidewall into the slot; and the first protrusions and the second protrusions are staggered.

Optionally, the extender comprises a conductive body having a lower portion extending through the groove and an upper portion disposed above the tower portion; and an insulative housing at least partially enclosing the upper portion of the conductive body.

Optionally, the conductive body comprises a first side portion extending from the upper portion to the lower portion; a second side portion extending from the upper portion to the lower portion; and an end portion joining the first side portion and the second side portion at the upper portion.

Optionally, the first and second side portions are either embedded in the insulative housing of the extender or disposed inside the tower portion.

Optionally, the body is elongated in a longitudinal direction; the tower is elongated in a vertical direction perpendicular to the longitudinal direction; and the tower is not wider than the body in a transverse direction perpendicular to both the longitudinal direction and the vertical direction.

Some embodiments relate to a method of manufacturing a memory card connector. The method may include providing a housing comprising a body having a mating face and a mounting face, a tower portion extending from an end of the body and having a groove extending beyond the mounting face of the body, and a slot recessed from the mating face of the body and extending into the tower portion; providing an extender comprising a first portion and a second portion; and inserting the second portion of the extender into the groove of the housing.

Optionally, the method may include assembling a latch to the tower portion of the housing, wherein at a locked position the latch extends above the tower portion and below the extender.

Optionally, providing the extender comprises overmolding an insulative material over a portion of a conductive body to form the first portion.

Some embodiments relate to an electrical connector. The electrical connector may comprise a housing that is provided with a first card slot extending in a longitudinal direction. The housing may include a body extending in the longitudinal direction and a tower portion extending from an end of the body in a vertical direction perpendicular to the longitudinal direction. The tower portion may be configured to engage an extender to form a tower together with the extender. The tower portion may have a first vertical height, and the tower may have a second vertical height greater than the first vertical height. The tower may be configured for a tall card to be inserted into the first slot, and the vertical height of the tall card may be greater than a standard vertical height of a standard card.

Optionally, the electrical connector may further comprise the extender engaged to the tower portion.

Optionally, the extender may comprise an extender body and an extender housing. The extender body may include an upper portion and a lower portion connected to each other. The lower portion may engage the tower portion. The upper portion may be higher than the tower portion in the vertical direction. The extender housing may wrap around the upper portion, and the extender housing may be disposed on the tower portion.

Optionally, the tower portion may be provided with a groove. The lower portion may be inserted into the groove so as to engage the tower portion.

Optionally, the groove may comprise a first groove and a second groove, which may be disposed on opposite sides of the first slot in a transverse direction perpendicular to the longitudinal direction and the vertical direction, respectively. The lower portion may include a first beam and a second beam. The first beam and the second beam may be inserted into the first groove and the second groove, respectively.

Optionally, the tower portion may comprise a first surface facing the extender in the vertical direction and a second surface facing away from the extender in the vertical direction. The tower portion may also comprise a first side surface and a second side surface opposed to each other in the transverse direction. The first groove is adjacent to the first side surface and the second groove is adjacent to the second side surface. The tower portion may be further provided with a first slit extending from the first surface toward the second surface and spaced apart from the second surface. The first slit may extend from the first groove to the first side surface in the transverse direction. The tower portion may be further provided a second slit extending from the first surface toward the second surface and spaced apart from the second surface. The second slit may extend from the second groove to the second side surface in the transverse direction.

Optionally, a barb may be provided on a side of the lower portion such that the lower portion is held in the groove.

Optionally, the extender body may be a one-piece member.

Optionally, the upper portion may comprise a first side portion and a second side portion opposed to each other in a transverse direction perpendicular to the longitudinal direction and the vertical direction, as well as an end portion connecting the first side portion and the second side portion. The extender may be provided with a second slot which extends in the vertical direction and aligned with the first slot. The second slot may be configured for receiving the side edge of a card. The second slot may extend into a space enclosed by the first side portion, the second side portion and the end portion, and the lower portion may be connected to the first side portion and the second side portion.

Optionally, the end portion may be provided with a through-hole. The extender housing may be formed onto the upper portion by overmolding.

Optionally, a top portion of the tower portion away from the body may extend into the space.

Optionally, the top portion may have a third side surface facing away from the first slot in the longitudinal direction. The end portion may include a bar covering the third side surface. Connecting portions of the first side portion and the second side portion connected to the lower portion may be inserted into the tower portion.

Optionally, a groove may be disposed within the tower portion. The bar may be outside of the extender housing and flush with a wall of the groove.

Optionally, every cross-section of the upper portion perpendicular to the vertical direction may be U-shaped.

Optionally, the end portion may be provided with an opening. The electrical connector may further comprise a latch which is movably connected to the tower portion and/or the extender between a locked position for locking the card inserted into the first slot and an unlocked position for releasing the card. The latch may pass through the opening to lock the card when in the locked position.

Optionally, the lower portion may be configured to extend beyond the tower portion, for engaging a circuit board to which the electrical connector is mounted.

Optionally, the extender may be configured for engaging a circuit board to which the electrical connector is mounted.

Optionally, the extender may be configured such that the tower in the vertical direction is not taller than a standard card inserted into the first slot.

Optionally, the extender may be provided with a second slot, which extends in the vertical direction and is aligned with the first slot. The second slot may be configured for receiving a side edge of the card.

Optionally, the second slot may have a first sidewall and a second sidewall opposed to each other in a transverse direction perpendicular to the longitudinal direction and the vertical direction. Each of the first sidewall and the second sidewall may be provided with a protrusion for providing limitation to the card in the transverse direction.

Optionally, at least one of the first sidewall and the second sidewall have a plurality of the protrusions. Optionally, the protrusion on the first sidewall and the protrusion on the second sidewall may be staggered in the vertical direction.

Optionally, the electrical connector may further comprise a latch movably connected to the tower portion between a locked position for locking the card inserted into the first slot and an unlocked position for releasing the card.

Optionally, the electrical connector may further comprise the extender engaged to the tower portion. The latch may pass through the extender to lock the card when in the locked position.

Some embodiments relate to an electrical connector comprising an housing with a first slot extending in a longitudinal direction. The housing may include a body extending in the longitudinal direction and a tower portion extending from an end of the body in a vertical direction perpendicular to the longitudinal direction. The tower portion may be configured to engage an extender to form a tower together with the extender. The tower portion may have a first vertical height, and the tower may have a second vertical height greater than the first vertical height. The tower portion may be connected with a latch. The latch may be positioned in the vertical direction such that the latch is capable of locking a standard card inserted into the first slot.

Optionally, the electrical connector may further comprise the extender engaged to the tower portion to form the tower. The tower may be configured for a tall card to be inserted into the first slot. The vertical height of the tall card may be greater than the standard vertical height of the standard card. The latch may be configured for passing through the extender to lock the standard card or the tall card.

Optionally, the extender may have a first end portion and a second end portion opposed to each other in the vertical direction, as well as an intermediate portion connecting the first end portion and the second end portion. The first end portion may engage the tower portion. The intermediate portion may be provided with an opening. The latch may pass through the opening to lock the standard card or the tall card.

Optionally, the second end portion may protrude outwardly beyond the intermediate portion in the longitudinal direction.

Optionally, the extender may comprise an extender body and an extender housing. The extender body may include an upper portion and a lower portion connected to each other, The lower portion may engage the tower portion. The upper portion may be higher than the tower portion in the vertical direction. The extender housing may wrap around the upper portion, and the extender housing may be disposed on the tower portion. The lower portion may form the first end portion, and the upper portion and the extender housing may form the intermediate portion and the second end portion.

Optionally, a width of the extender may be adapted to a width of the tower portion in a transverse direction perpendicular to the longitudinal direction and the vertical direction.

Optionally, the latch may be pivotably connected to the tower portion. The latch may include a handle. A longitudinal length of the handle may be greater than that of an handle of a latch of a standard electrical connector adapted to the standard card.

Optionally, the housing may be dimensioned to be in conformity with the standard electrical connector adapted to the standard card in the longitudinal direction and a transverse direction that is perpendicular to the longitudinal direction and the vertical direction.

These techniques may be used alone or in any suitable combination. The foregoing summary is provided by way of illustration and is not intended to be limiting.

### BRIEF DESCRIPTION OF DRAWINGS

The accompanying drawings may not be drawn to scale. In the drawings, each identical or nearly identical component that is illustrated in various figures may be represented by a like numeral. For purposes of clarity, not every component may be labeled in every drawing. In the drawings:

FIG. 1 is a perspective view of an electronic system, showing an electrical connector with a latch in a locked position and connected to a tall add-in card, according to some embodiments;

FIG. 2 is a perspective view of an electronic system, showing the electrical connector of FIG. 1 with the latch in the locked position and connected to a standard add-in card (e.g., according to DDR5 or below);

FIG. 3 is an enlarged perspective view of a portion of the electronic system of FIG. 1;

FIG. 4 is a perspective view of the electrical connector of FIG. 1, showing an extender, according to some embodiments;

FIG. 5 is a perspective view of the electrical connector of FIG. 4, with the extender hidden;

FIG. 6 is an enlarged perspective view of a portion of the electrical connector of FIG. 4;

FIG. 7 is a cross-sectional perspective view of a portion of the electrical connector as shown in FIG. 4;

FIG. 8 is an enlarged perspective view of a portion of the electrical connector of FIG. 4, with the latch hidden;

FIG. 9 is a perspective view of the extender of the electrical connector of FIG. 4;

FIG. 10 is a perspective view of a extender housing of the extender of FIG. 9;

FIG. 11 is a perspective view of an extender body of the extender of FIG. 9 at an angle;

FIG. 12 is a perspective view of the extender body of FIG. 11 at another angle;

FIG. 13 is an enlarged perspective view of a portion of a housing of the electrical connector of FIG. 4; and

FIG. 14 is a perspective view of the latch of the electrical connector of FIG. 4.

The above accompanying drawings include the following reference signs:
100—electrical connector; 200—housing; 201—mating face; 202—mounting face; 210—first card slot; 220—body; 221—end; 230—tower portion; 231—first surface; 232—second surface; 233—first side surface; 234—second side surface; 235—third side surface; 236—top portion; 240—groove; 241—first groove; 242—second groove; 251—first slit; 252—second slit; 260—groove; 261—hole; 300—conductive element; 310—mating portion; 320—tail portion; 400—extender; 401—first end portion; 402—second end portion; 403—intermediate portion; 410—extender body; 420—upper portion; 421—first side portion; 422—second side portion; 4211, 4221—connecting portion; 423—end portion; 424—through-hole; 425—bar; 426—opening; 427—space; 430—lower portion; 431—first beam; 432—second beam; 433—barb; 440—extender housing; 441—extension; 450—second card slot; 451—first sidewall; 452—second sidewall; 453—protrusion; 500—tower; 600—latch; 610—pivot shaft; 620—handle; 630—rib; 911—tall add-in card; 912—standard add-in card (e.g., according to DDR5 or below); 920—circuit board; 921—hole; 930—board lock.

### DETAILED DESCRIPTION

The Inventors have recognized and appreciated connector design techniques for economically making electrical connectors that can reliably operate with different mating components. Different mating components may have different dimensions. For example, tall cards may enable greater functionality of the system, as tall cards may have greater heights than standard cards (e.g., according to DDR5 or below) so as to provide more functions and/or storage (e.g., high-capacity memory modules). A standard DDR5 card has a height of about 32 mm and notches disposed about ½ height of the card or lower configured for engaging latches. A tall card would have a greater height, which can be, for example, one and half or two times the height of a standard card.

The Inventors have recognized and appreciated that connectors with conventional designs, however, would not be able to provide the strengths for reliable connections between tall cards and the connectors. On the other hand, connectors that can provide the strengths for reliable connections between tall cards and the connectors would not be able to mate with a standard card. Techniques describe herein enable configurable electrical connectors, which are compatible with and can provide reliable connections for both standard cards and tall cards.

According to aspects of the present application, an electrical connector may have a housing body, a tower extending from the housing body and beyond a mating face, and a latch movably coupled to the housing body and/or tower. The tower may be configurable according to a mating component. The tower can be a tower portion formed with the housing body. The tower can include an extender, with a lower portion disposed inside the tower portion and an upper portion disposed on the tower portion. The extender may have an opening through which the latch can pass for engaging a mating component at the locked position. Such a configuration may enable the connector to reliably hold a tall card while still capable of mating with a standard card, and therefore enable the connector to be compatible with both standard cards and tall cards so as to support different storage capacities and data rates.

An electrical connector according to some embodiments of the present disclosure is described in detail hereinbelow in conjunction with the drawings. A vertical direction Z-Z, a longitudinal direction X-X and a transverse direction Y-Y may be shown in the drawings. The vertical direction Z-Z, the longitudinal direction X-X and the transverse direction Y-Y may be perpendicular to one another. The vertical direction Z-Z may refer to a height direction of the electrical connector, which in this example is a direction from the mounting interface of the connector towards a surface containing slots that receive a mating component. The longitudinal direction X-X may refer to a length direction of the electrical connector. The transverse direction Y-Y may refer to a width direction of the electrical connector, with the connector being elongated in the length direction and narrower in the width direction than the length direction.

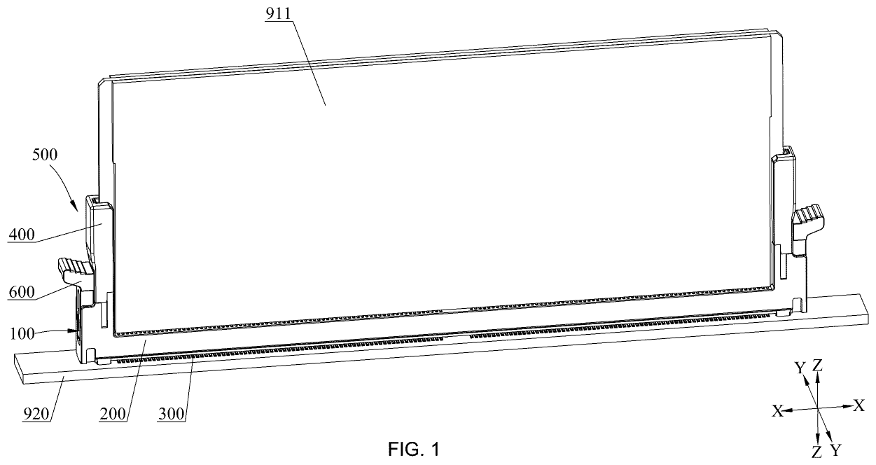

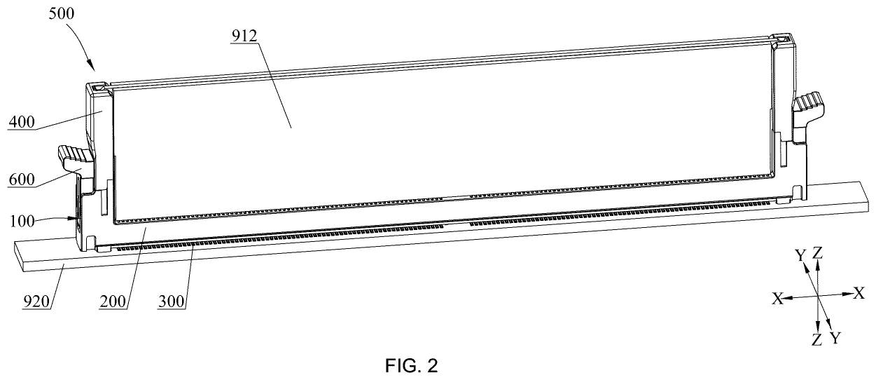

FIGS. 1 and 2 show the interconnection of a tall add-in card 911 and a standard add-in card 912 with a printed circuit board 920 using a memory card connector 100, respectively, according to some embodiments of the present disclosure. The tall add-in card 911 and the standard add-in card 912 may have substantially the same longitudinal length and transverse width, while their vertical heights may differ. For example, the tall add-in card 911 can be one and half or two times the height of the standard add-in card 912. The tall add-in card 911 and the standard add-in card 912 therefore can provide different storage capacities and data rates. The standard add-in card 912 may be an add-in card complying with industry standards such as DDR5 or below provided by Joint Electron Device Engineering Council (JEDEC). As illustrated, the connector 100 is compatible with both the tall add-in card 911 and the standard add-in card 912.

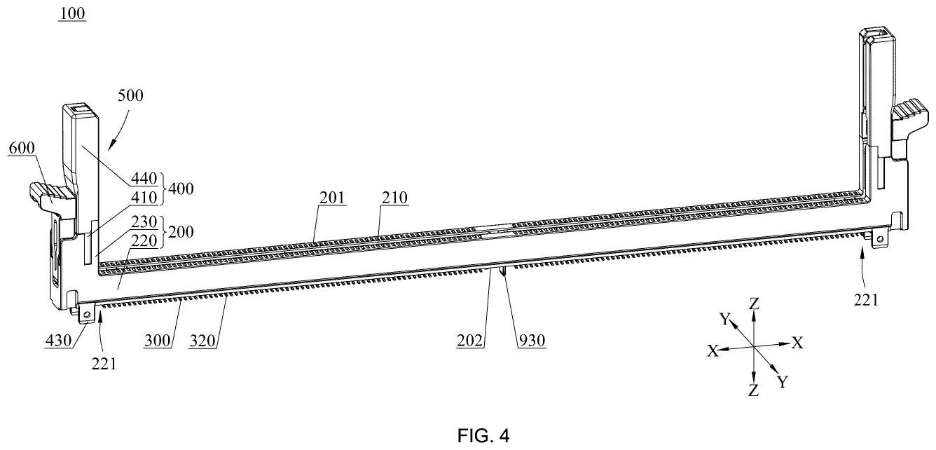

The connector 100 may comprise a housing 200. As shown in FIG. 4, the housing 200 may have a mating face 201 and a mounting face 202. The mating face 201 and the mounting face 202 may be disposed opposite each other in a vertical direction Z-Z. The mating face 201 may be provided with a first card slot 210. Exemplarily, the first card slot 210 may be recessed inward from the mating face 201 in the vertical direction Z-Z. The first card slot 210 may be configured to receive at least a part of the add-in card, for example, the bottom edge of the add-in card, to hold the add-in card in the housing 200. The add-in card may function as a daughter card. The connector 100 may be connected to a main board, such as a circuit board 920, such that a plurality of daughter cards can be interconnected with the main board by disposing a plurality of connectors 100 on the main board. The add-in cards may include one or more of a graphics card, a memory card, a sound card, etc.

The housing 200 may be molded with an insulative material, such as a plastic. Various types of plastics may be used such as, but not limited to, liquid crystal polymers (LCP), polyphenylene sulfite (PPS), high-temperature nylon or poly-phenylene oxide (PPO), or polypropylene (PP). Other suitable materials may also be employed. In some cases, the plastic may be a thermoset plastic. In some cases, the insulative plastic may include insulative reinforcing material such as glass fibers. The housing 200 may generally be a one-piece member. The housing 200 may be an injection molded piece.

Exemplarily, the housing 200 may comprise a body 220 and a tower portion 230. The body 220 may extend in a longitudinal direction X-X. The body 220 has ends 221 disposed opposite each other in the longitudinal direction X-X, as shown in FIG. 4. Exemplarily, only one end 221 of the body 220 may be connected with the tower portion 230. Preferably, the ends 221 of the body 220 each may be connected with the tower portion 230 as shown. The tower portion 230 may extend from the corresponding end 221 of the body 220 in the vertical direction Z-Z. The tower portion 230 may protrude beyond the body 220 at the end of the body 220 in the vertical direction Z-Z. The first card slot 210 may extend from the body 220 into the tower portion 230. In this way, the first card slot 210 may be U-shaped. The bottom edge of the add-in card and the parts of the two side edges close to the bottom edge may be inserted into the first card slot 210.

The connector 100 may comprise a plurality of conductive elements 300. The plurality of conductive elements 300 may be held in the housing 200. For example, the plurality of conductive elements 300 may be spaced apart from each other in the longitudinal direction X-X held in the housing 200 to ensure that adjacent conductive elements 300 are electrically insulated from each other. The plurality of conductive elements 300 may be disposed in the body 220. The conductive elements 300 may be arranged in two columns in the longitudinal direction X-X on opposite sides of the first card slot 210. Optionally, the two columns of conductive elements 300 may be aligned with each other in the longitudinal direction X-X. Optionally, the two columns of conductive elements 300 may be staggered in the longitudinal direction X-X to increase the space between the conductive elements 300, thereby reducing crosstalk. Optionally, the two columns of conductive elements 300 have the same construction and are simply configured in mirror image of each other. Optionally, the conductive elements 300 may be disposed on only one side of the first card slot 210.

The conductive elements 300 may be made of an electrically conductive material, such as metal. The conductive elements 300 may be elongated one-piece members. Each conductive element 300 may comprise a mating portion 310 and a tail portion 320 disposed at two ends of the conductive element 300. The mating portion 310 may be disposed within the housing 200. The mating portion 310 may be disposed on the side of the first card slot 210. For example, the mating portion 310 may be bent toward the first card slot 210 to protrude into the first card slot 210. The add-in card may have a plurality of adaptive conductive elements, such as gold fingers. When the add-in card is inserted into the first card slot 210, the mating portion 310 can be electrically connected to a corresponding adaptive conductive element on the add-in card, thereby achieving electrical connection of the conductive elements 300 to the circuits in the add-in card. The tail portion 320 may extend beyond the housing 200. For example, the tail portion 320 may extend beyond the mounting face 202 of the housing 200. The tail portion 320 may be connected to the circuit board 920 by for example Surface Mounted Technology (SMT) and/or Through-Hole Technology (THT). In this way, the connector 100 can be electrically connected to the circuit board 920.

The connector 100 may comprise a latch 600. Exemplarily, only one end of the housing 200 may be provided with the latch 600. Exemplarily, both ends of the housing 200 each may be provided with the latch 600. The latch 600 may be molded from an insulative material, such as a plastic, by molding process. The latch 600 may be a one-piece member. The materials of the latch 600 and the housing 200 may be the same or different. The latch 600 is movable between a locked position and an unlocked position. The movement forms of the latch 600 between the locked position and the unlocked position may include, but is not limited to, pivoting or translating. The latch 600 can be locked to the add-in card inserted into the first card slot 210 when in the locked position, such that the add-in card inserted into the first card slot 210 is firmly connected to the housing 200. The add-in card is prevented from being separated from the first card slot 210. When the latch 600 is in the unlocked position, the add-in card can be released. During insertion of the add-in card into the first card slot 210, the latch 600 may be in the unlocked position.

The tower portion 230 may be configured to engage an extender 400. The extender 400 may engage the tower portion 230 by insertion, a fastener or any other suitable methods. When the extender 400 engages the tower portion 230, the tower portion 230 may together with the extender 400 form a tower 500. The tower portion 230 may have a first vertical height. As a result of the engagement of the extender 400 to the tower portion 230, the tower 500 may have a second vertical height greater than the first vertical height. Referring to FIG. 1, the tower 500 may be configured to be adapted to the tall add-in card 911 inserted into the first card slot 210. The vertical height of the tall add-in card 911 may be greater than that of the standard add-in card 912 as shown in FIG. 2. The adaptation of the tower 500 to the tall add-in card 911 inserted into the first card slot 210 may indicate that the waggle of the top of the tall add-in card 911, for example, in a transverse direction Y-Y, is within a permitted range during the operation of the system. The second vertical height of the tower 500 may not be equal to the height of the tall add-in card 911. As illustrated in FIG. 2, the second vertical height of the tower 500 may substantially equal to the height of a standard add-in card 912 for example. The waggle being within the permitted range may be determined by many factors, such as the service life of the connector (prominent waggle may lead to a susceptibility to damage of the housing), as well as the electrical properties of the interconnection system including the connector, the add-in card, the circuit board, etc.

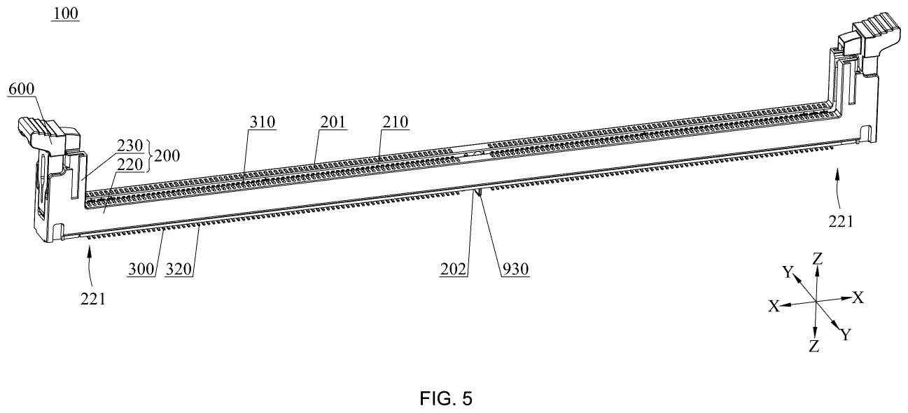

Exemplarily, the first vertical height may be comparable to the tower of the housing of the standard connector. As shown in FIG. 5, when the extender 400 is not installed, the latch 600 may still be adapted to the tower portion 230. In this way, the latch 600 may have the standard add-in card 912 locked to the housing 200 if the standard add-in card 912 is inserted into the first card slot 210. As will be described later, in order to engage the extender 400, a groove 240 may be provided in the tower portion 230. The extender 400 may be connected with the tower portion 230 by being inserted into the groove 240. When the extender 400 is not installed, a strengthening member (not shown) may be optionally inserted into the groove 240, thereby increasing the mechanical strength of the tower portion 230. The strengthening member may be of the same or similar structure as the part of the extender 400 that engages the tower portion 230. The second vertical height may be adapted to the height of the tall add-in card 911. Exemplarily, the second vertical height may be substantially equal to ½ of the height of the tall add-in card 911, or up to ⅔ of its height, or in the range of ½ to ⅔ of the height of the tall add-in card 911. It should be appreciated that the present disclosure does not exclude the situation that the second vertical height is less than ½ of the height of the tall add-in card 911 or greater than ⅔ of the height of the tall add-in card 911. In order to enable the latch 600 to be locked with either the tall add-in card 911 or the standard add-in card 912, a notch on the side of the tall add-in card 911 for locking with the latch 600 may have the same structure and position as that of the standard add-in card 912.

It should be appreciated that when the extender 400 is joined with the tower portion 230, as shown in FIG. 2, the connector may still be connected with the standard add-in card 912. The top of the extender 400 may be at a level of the upper edge of the standard add-in card 912 in height as shown in FIG. 2, or may be lower than the upper edge of the standard add-in card 912, or may be taller than the upper edge of the standard add-in card 912. Exemplarily, the extender 400 may be configured such that the tower 500 is not taller than the standard add-in card 912 inserted into the first card slot 210 in the vertical direction Z-Z. Further, the top surface of the extender 400 may be at the same height as that of the standard add-in card 912 inserted into the first card slot 210. It should be appreciated that in the embodiment where the top of the extender 400 is approximately level with the upper edge of the standard add-in card 912, the extender 400 may not protrude from the standard add-in card 912 and may provide adequate fixation for both side edges of the standard add-in card 912 when the standard add-in card 912 is inserted. The extender 400 may provide fixation for as many parts of the tall add-in card 911 as possible when the tall add-in card 911 is inserted.

Exemplarily, in the transverse direction Y-Y, the transverse width of the extender 400 may be adapted to that of the tower portion 230. With this configuration, the extender 400 will not lead to an increase in the transverse dimension of the connector 10, thus the connector 100 can be backward compatible, for example, compatible with the standard add-in card 912. Exemplarily, the housing 200 may be dimensioned in the longitudinal direction X-X and the transverse direction Y-Y to be in conformity with the standard connector adapted to the standard add-in card 912. With this configuration, the connector 100 can replace the standard connector directly without having to change the structures or positions of other components adjacent to it, and the product development cycle is shortened.

In the connector 100 provided by the embodiments of the present disclosure, the extender 400 engages the tower portion 230 to form the taller tower 500, which may have the second vertical height. In this way, the connector 100 may provide adequate limitation and fixation for both side edges of the tall add-in card 911. The waggle of the tall add-in card 911 can be effectively suppressed during use, thereby improving signal transmission stability and protecting the housing 200 from damage caused by the waggle of the tall add-in card 911. The longitudinal length and the transverse width of the connector 100 may comply with industrial standards such as JEDEC standards. As well, since the tower portion 230 may be joined with the extender 400, the connector 100 may be compatible with both the tall add-in card 911 and the standard add-in card 912 such that the connector 100 has a higher degree of compatibility.

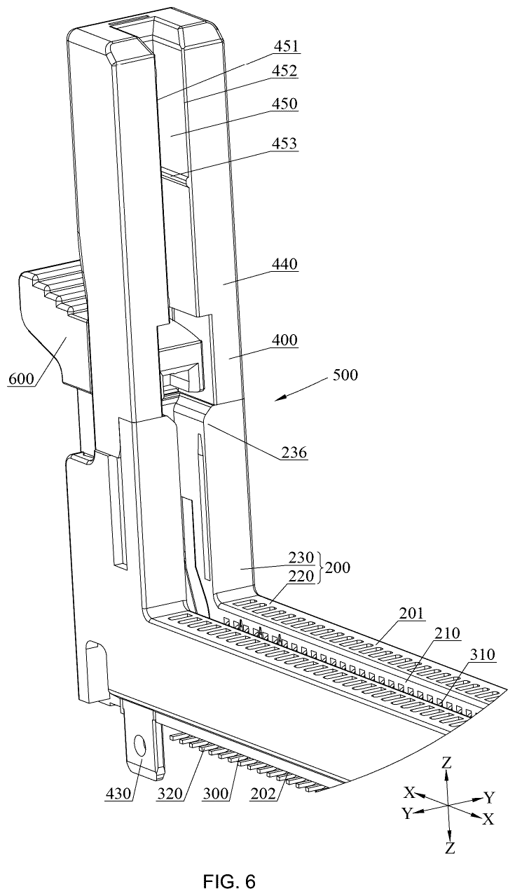

Exemplarily, a second card slot 450 may be provided in the extender 400, as shown in FIG. 6. The second card slot 450 may extend in the vertical direction Z-Z. The second card slot 450 may be aligned with the first card slot 210. The second card slot 450 may be configured to receive the side edges of the add-in card. The add-in card may be inserted first into the second card slot 450 and then into the first card slot 210 along the second card slot 450. The second card slot 450 may therefore provide a better limitation and fixation effect on the add-in card. The second card slot 450 may also act as a guide, facilitating the smooth insertion of the add-in card into the first card slot 210.

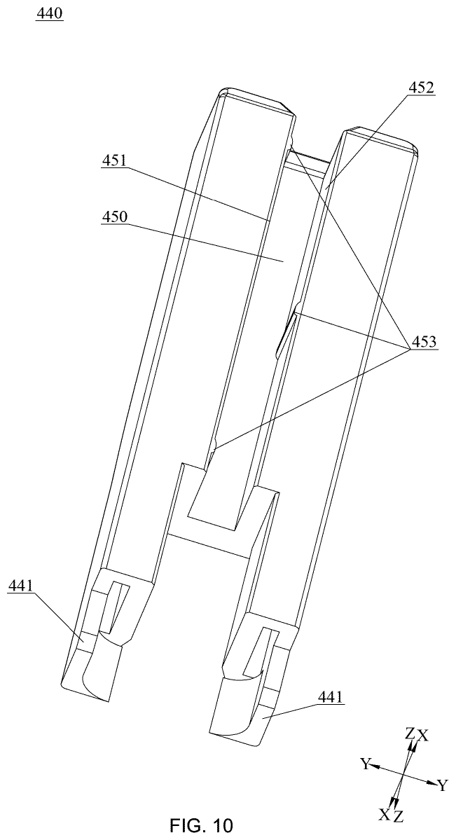

Exemplarily, the second card slot 450 may have a first sidewall 451 and a second sidewall 452, as shown in FIGS. 6 and 10. The first sidewall 451 and the second sidewall 452 may be provided opposite each other in the transverse direction Y-Y. The first sidewall 451 and the second sidewall 452 each may be provided with a protrusion 453. The protrusions 453 may be configured to limit the position of the add-in card in the transverse direction Y-Y. If no protrusion is provided, the first sidewall 451 and the second sidewall 452 may tightly abut against the front and back of the add-in card respectively when the add-in card is inserted into the connector 100, such that the add-in card is securely fixed to the connector 100. As mentioned above, before the add-in card is inserted into the first card slot 210 in place, both side edges of the add-in card may slide in the second card slot 450. If the first sidewall 451 and the second sidewall 452 completely tightly abut against the front and back of the add-in card, respectively, this may result in excessive resistance to the insertion of the add-in card into the connector 100 and both side edges of the add-in card may be worn severely. When the protrusions 453 are provided, during the sliding of the add-in card along the second card slot 450, the protrusions 453 are in contact with the add-in card and generate friction, thereby reducing the resistance generated when inserting/removing the add-in card, and avoiding significant wear on the add-in card.

Exemplarily, the protrusion 453 on the first sidewall 451 and the protrusion 453 on the second sidewall 452 may be staggered in the vertical direction Z-Z. In the embodiment as shown in the figures, two protrusions 453 may be provided on the first sidewall 451 and one protrusion 453 may be provided on the second sidewall 452. It should be appreciated that the number of the protrusions 453 on the first sidewall 451 and/or the number of the protrusions 453 on the second sidewall 452 may be greater or less. In the vertical direction Z-Z, the protrusion 453 on the second sidewall 452 may be disposed between the two protrusions 453 on the first sidewall 451. During insertion, the first sidewall 451 and the second sidewall 452 may be slightly deformed, which can reduce the wear on the protrusions 453. The staggered design of the protrusions 453 on the first sidewall 451 and the second sidewall 452 may appropriately reduce the resistance to the add-in card during its insertion into the second card slot 450, for example at the initial insertion stage of the add-in card when the add-in card is scraped by only one protrusion 453 on one side. The resistance may gradually increase as the insertion process proceeds, such that the add-in card can be prevented from lunging once an excessive external force is applied. It may be possible to determine whether the insertion is in place or not based on the increase in insertion force. During the insertion of the lower portion of the add-in card, the narrowest part is always between one of the first sidewall 451 and the second sidewall 452 as well as the protrusion 453 on the opposite side thereof, while the width of this part is greater than the thickness of the add-in card. Such a configuration may enable the add-in card to travel forward smoothly.

Exemplarily, at least one of the first sidewall 451 and the second sidewall 452 have a plurality of the protrusions 453, as shown in FIG. 10. The plurality of protrusions 453 may prevent the add-in card from being deformed due to uneven force upon the add-in card after it is inserted in place, for example when the protrusions 453 on the first sidewall 451 and the second sidewall 452 are staggered in the vertical direction Z-Z.

In some embodiments, the extender 400 may comprise an extender body 410 and a extender housing 440. The extender body 410 may be made of a material with stronger mechanical strength, such as metal. The extender body 410 may be a one-piece member. In this way, the extender body 410 can be processed costly and have higher mechanical strength. The extender body 410 may comprise an upper portion 420 and a lower portion 430. The upper portion 420 and the lower portion 430 may be connected to each other. The lower portion 430 may engage the tower portion 230 by any suitable methods such as insertion or a fastener. The upper portion 420 may be disposed higher than the tower portion 230 in the vertical direction Z-Z. In this way, the extender body 410 may act as a framework for the extender 400, thereby providing sufficient mechanical strength for the extender 400. The extender housing 440 may wrap around the upper portion 420. The extender housing 440 may be disposed outside the tower portion 230. The extender housing 440 may be overmolded from a thermosetting material, such as a plastic, onto the extender body 410. The material of the extender housing 440 may be the same as or different from that of the housing 200. The extender housing 440 may provide protection to the upper portion 420, thereby preventing problems such as short circuits.

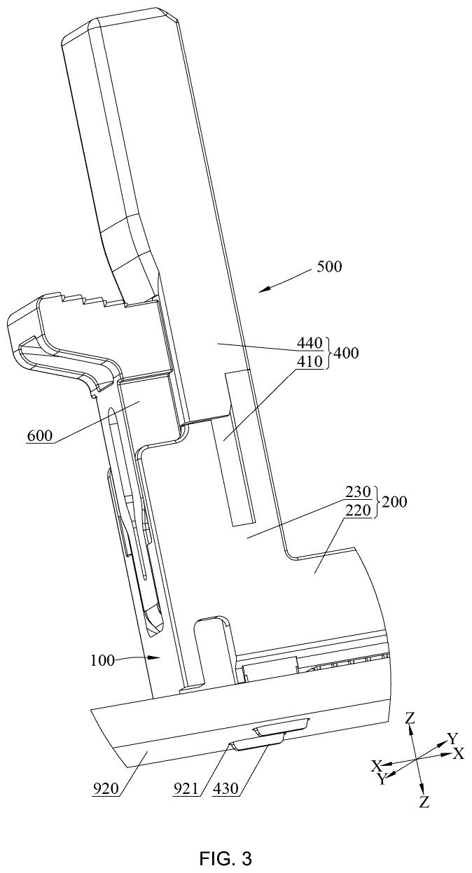

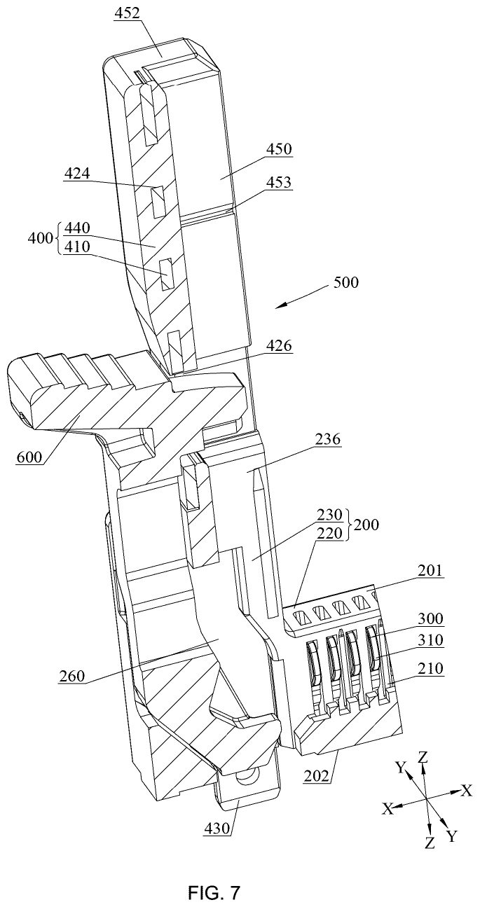

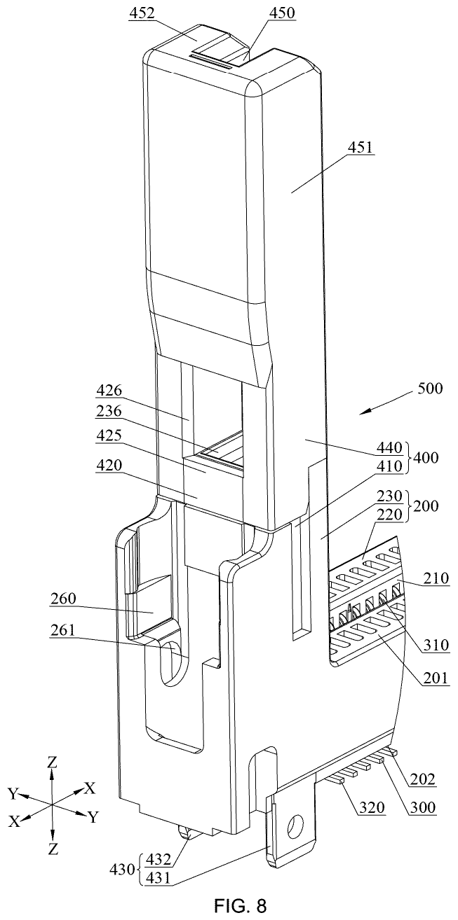

Exemplarily, the extender 400 may be configured for engaging the circuit board 920 mounted with the connector 100. The extender 400 may engage the circuit board 920 in any suitable manner, including but be not limited to soldering or insertion. Exemplarily, the lower portion 430 may be configured to extend beyond the tower portion 230, as shown in FIGS. 6-8. For example, the lower portion 430 may extend beyond the mounting face 202 of the housing 200. The lower portion 430 may be configured for engaging the circuit board 920 mounted with the connector 100. In some embodiments, the circuit board 920 may be provided with a hole 921, as shown in FIG. 3. The lower portion 430 may be inserted into and soldered to the hole 921. With this configuration, the connector 100 can be firmly attached to the circuit board 920, and the stability of the connector 100 is improved in overall. The lower portion 430 may be connected to the circuit board 920 by soldering. With this configuration, the connector 100 engages the circuit board 920 with a higher strength, thereby enabling a higher stability of the connector 100 in overall. As illustrated, the extender housing 440 and the upper portion 420 may be disposed on an opposite side to the circuit board 920 relative to the tower portion 230 in the vertical direction Z-Z, respectively, such that the extender housing 440 and the upper portion 420 together with the circuit board 920 can hold the tower portion 230 between them, and thus the housing 200 can be firmly fixed to the circuit board 920.

Exemplarily, the connector 100 may further comprise a board lock 930, as shown in FIGS. 4-5. One end of the board lock 930 may be inserted into the housing 200. The other end of the board lock 930 may be inserted into the circuit board 920. With this configuration, the connector 100 can be firmly connected with the circuit board 920, thereby allowing for a higher overall stability of the connector 100. Since the tower portion 230 may be fixed to the circuit board 920 via the extender 400, a board lock at the end of the housing 200 may be omitted and only the board lock 930 is provided in the middle of the housing 200, thereby simplifying the structure of the connector 100 and reducing the number of parts. Exemplarily, the conductive elements 300 may be in electrical contact with soldering pads on the circuit board 920 by press fit. This further simplifies the assembly process, and it becomes easier to change the connector 100 as desired, simply by disconnecting the extender body 410 from the circuit board 920 and the board lock 930 from the circuit board 920. It should be appreciated that the present disclosure does not exclude the embodiments in which the conductive elements 300 are soldered to the circuit board 920.

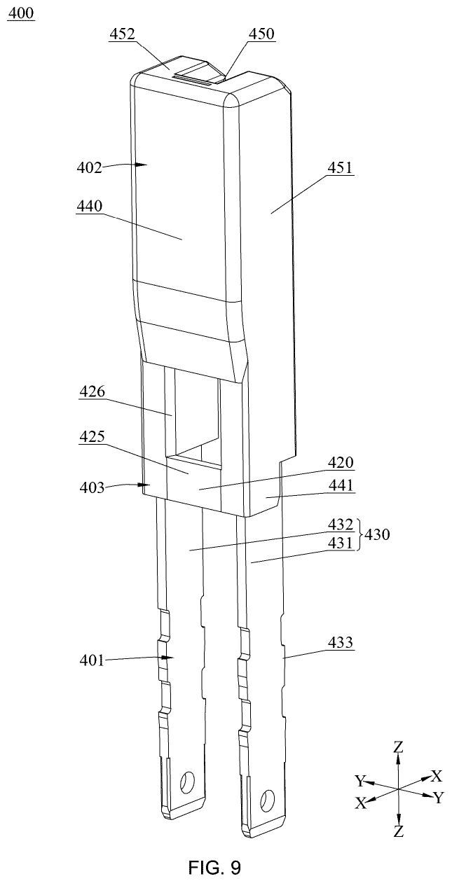

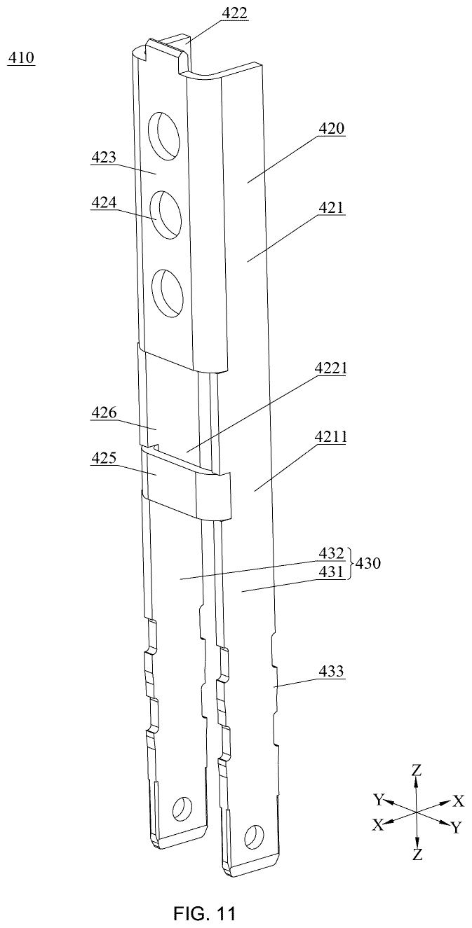

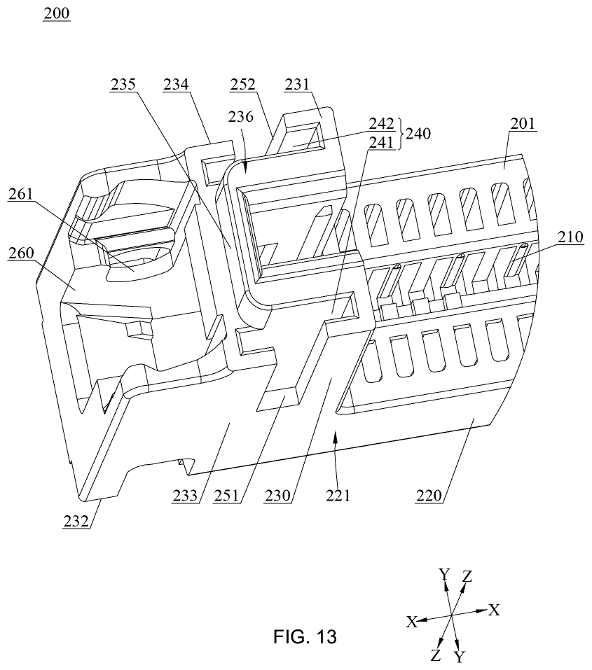

Exemplarily, the tower portion 230 may be provided with a groove 240, as shown in FIG. 13. The lower portion 430 may be inserted into the groove 240 such that the lower portion 430 can be joined with the tower portion 230. In this way, the extender 400 can be easily assembled with the housing 200, thereby reducing product cost. It should be appreciated that the extender 400 can have a strengthening effect on the housing 200 by inserting the extender body 410 into the housing 200, since the extender body 410 has a higher mechanical strength. Exemplarily, the groove 240 may comprise a first groove 241 and a second groove 242. The first groove 241 and the second groove 242 may be disposed on opposite sides of the first card slot 210 in the transverse direction Y-Y, respectively. The lower portion 430 may comprise a first beam 431 and a second beam 432, as shown in FIGS. 9 and 11. The first beam 431 and the second beam 432 may be inserted into the first groove 241 and the second groove 242, respectively. For example, the first beam 431 may be inserted into the first groove 241; and the second beam 432 may be inserted into the second groove 242. With this configuration, the lower portion 430 and the groove 240 can engage at multiple positions, thereby increasing the engagement strength. The first beam 431 and the second beam 432 may provide protection to the first card slot 210 in the transverse direction Y-Y, such that the housing 200 can be prevented from the damage due to the waggle of the tall add-in card 911.

Exemplarily, a barb 433 may be provided on a side of the lower portion 430, as shown in FIGS. 9 and 11. In this way, the lower portion 430 can be held within the groove 240. In the embodiment where the groove 240 comprises the first groove 241 and the second groove 242, the barbs 433 may be provided on the sides of both the first groove 241 and the second groove 242. The barbs 433 may make interference fit with the wall of the groove 240, thereby preventing the lower portion 430 from being easily pulled out of the groove 240. The engagement strength of the lower portion 430 with the groove 240 may therefore be improved.

Exemplarily, the tower portion 230 may have a first surface 231, a second surface 232, a first side surface 233 and a second side surface 234, as shown in FIG. 13. The first surface 231 and the second surface 232 may be disposed opposite each other in the vertical direction Z-Z. The first surface 231 may face the extender 400 in the vertical direction Z-Z. The second surface 232 may face away from the extender 400 in the vertical direction Z-Z. The first side surface 233 and the second side surface 234 may be disposed opposite each other in the transverse direction Y-Y. The first groove 241 may be adjacent to the first side surface 233. The second groove 242 may be adjacent to the second side surface 234. Exemplarily, the tower portion 230 may also be provided with a first slit 251. The first slit 251 may extend from the first surface 231 toward the second surface 232. the first slit 251 may be spaced apart from the second surface 232. The first slit 251 may extend from the first groove 241 to the first side surface 233 in the transverse direction Y-Y. The first groove 241 communicates with the outer side via the first slit 251 in the transverse direction Y-Y. The first groove 241 can be avoided to be in tabular shape. In this way, the molds for injection molding the insulating shell 200 can have greater mechanical strength, thereby facilitating the production of the molds for the housing 200. Exemplarily, the tower portion 230 may also be provided with a second slit 252. The second slit 252 may extend from the first surface 231 toward the second surface 232. The second slit 252 may be spaced apart from the second surface 232. The second slit 252 may extend from the second groove 242 to the second side surface 234 in the transverse direction Y-Y. The second groove 242 communicates with the outer side via the second slit 252 in the transverse direction Y-Y, the second groove 242 can be avoided to be in tabular shape. In this way, the molds for injection molding the insulating shell 200 can have greater mechanical strength, thereby facilitating the production of the molds for the housing 200.

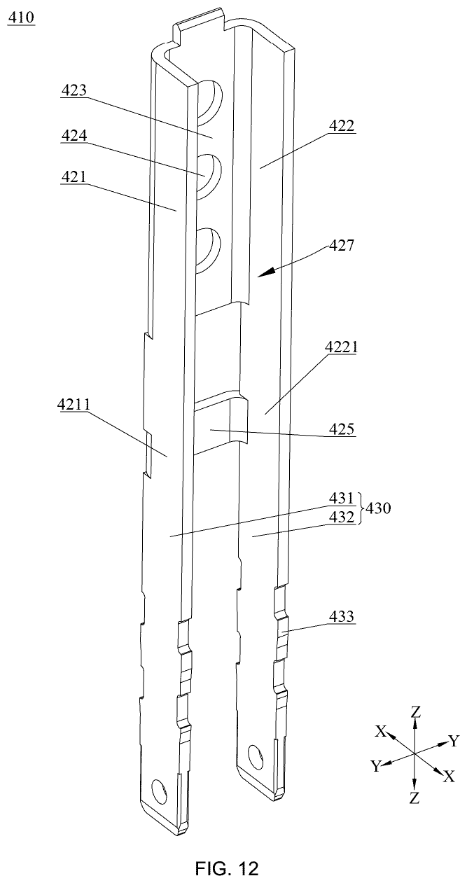

Exemplarily, as shown in FIGS. 11-12, the upper portion 420 may comprise a first side portion 421, a second side portion 422 and an end portion 423. The first side portion 421 and the second side portion 422 may be disposed opposite each other in the transverse direction Y-Y. The end portion 423 may connect the first side portion 421 and the second side portion 422. In this way, the first side portion 421, the second side portion 422 and the end portion 423 may enclose a space 427. The second card slot 450 may extend into the space 427. The lower portion 430 may be connected to the first side portion 421 and the second side portion 422. With this configuration, the second card slot can be less deformed by the upper portion 420, thereby providing better positioning and support for the edge of the add-in card inserted into the second card slot 450.

Exemplarily, the end portion 423 may be provided with a through-hole(s) 424. The number of the through-hole(s) 424 may be arbitrary, including but not limited to one, two or more. The extender housing 440 may be overmolded onto the upper portion 420 and filled in the through-hole 424. With this configuration, the extender housing 440 is attached to the upper portion 420 more firmly. It should be appreciated that by disposing the through-hole(s) 424 in the end portion 423, the first side portion 421 and the second side portion 422 can be unaffected in the structural strength, thereby providing better positioning and support to the add-in card.

Exemplarily, as shown in FIGS. 6-8 and 13, the tower portion 230 may have a top portion 236. The top portion 236 is an end of the tower portion 230 away from the body 220, e.g., the end being away from the circuit board 920. The top portion 236 may extend into the space 427 such that the top portion 236 of the tower portion 230 can be surrounded on three sides by the upper portion 420, and the mechanical strength of the tower portion 230 is enhanced. It should be appreciated that since the upper portion 420 extends into the tower portion 230, the length of lower portion 430, for example, the shape of a cantilever in the vertical direction Z-Z can be shortened, which also allows the lower portion 430 to have a sufficiently high mechanical strength.

Exemplarily, the top portion 236 of the tower portion 230 may have a third side surface 235. The third side surface 235 may be disposed on the side of the top portion 236 away from the body 220. The third side surface 235 may face away from the first card slot 210 in the longitudinal direction X-X. The end portion 423 of the upper portion 420 may comprise a bar 425 covering the third side surface 235. The first side portion 421 and the second side portion 422 of the upper portion 420 have respective connecting portions 4211 and 4221 connected to the lower portion 430, as shown in FIGS. 11-12. The top portion 236 of the tower portion 230 may extend into the space enclosed by the connecting portions 4211 and 4221 and the bar 425. With this configuration, the mechanical strength of the tower portion 230 may be enhanced by the upper portion 420. Exemplarily, cross-section of the upper portion 420 perpendicular to the vertical direction Z-Z may be U-shaped. The cross-section may be parallel to the longitudinal direction X-X and the transverse direction Y-Y. In this way, the upper portion 420 can be manufactured effectively and costly. The first side portion 421 and the second side portion 422 may be embedded in the extender housing 440, referring to FIGS. 9-10. Optionally, subject to the space in the tower portion 230, the bar 425 may be disposed outside the tower portion 230 and not be wrapped by the extender housing 440.

The bottom of the extender housing 440 may have extensions 441. The extensions 441 may be on the outside of the upper portion 420 over the connecting portions 4211 and 4221 of the upper portion 420, respectively. The inner surfaces of the connecting portions 4211 and 4221 may directly abut against the top portion 236 of the tower portion 230.

Exemplarily, the latch 600 may be connected to the tower portion 230 and/or the extender 400 between the locked position and the unlocked position. In some embodiments, the latch 600 may be movably disposed on the tower portion 230 between the locked position and the unlocked position. Exemplarily, the latch 600 is positioned in the vertical direction Z-Z such that the latch 600 is capable of locking the standard add-in card 912 inserted into the first card slot 210. In this way, the latch 600 may also lock the tall add-in card 911 inserted into the first card slot 210 by configuring the tall add-in card 911 in a reasonable manner. Thus, the latch 600 can be compatible with both the tall add-in card 911 and the standard add-in card 912.

Exemplarily, a groove 260 may be provided within the tower portion 230. The groove 260 may be configured to mount the latch 600. In the longitudinal direction Y-Y, the groove 260 may be disposed on the outside of the lower portion 430. The bar 425 may be disposed outside the extender housing 440. Additionally or alternatively, the bar 425 may be flush with a wall of the groove 260. The latch 600 may abut against the bar 425 when in the locked position. With this configuration, the bar 425 can be configured to limit the latch 600 connected to the groove 260, thereby preventing the latch 600 from deviating from its expected position. Exemplarily, the latch 600 is pivotably connected to the tower portion 230. For example, a hole 261 may be disposed in the groove 260. The latch 600 may be provided with a pivot shaft 610. With the insertion of the pivot shaft 610 into the hole 261, the latch 600 is pivotable relative to the tower portion 230.

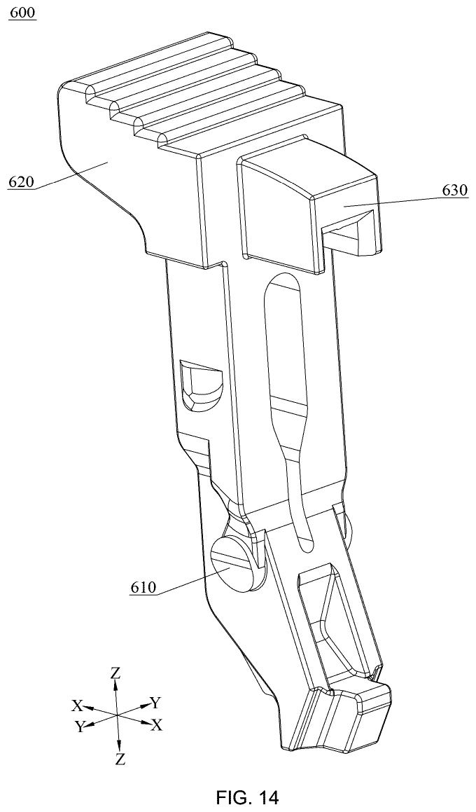

Exemplarily, the latch 600 may comprise a handle 620, as shown in FIG. 14. The handle 620 and the pivot shaft 610 may be disposed at opposite ends of the latch 600. The end where the handle 620 is may be provided with a rib 630. The rib 630 driven by the handle 620 may be inserted into the notch of the side of the add-in card or be removed from the notch, to achieve the locking and unlocking of the add-in card. The longitudinal length of the handle 620 may be greater than that of the handle of the latch of the standard electrical connector adapted to the standard add-in card. With this configuration, the handle 620 is more user-friendly and comfortable to operate.

Exemplarily, the extender 400 may have a first end portion 401, a second end portion 402 and an intermediate portion 403, as shown in FIG. 9. The first end portion 401 and the second end portion 402 may be disposed opposite each other in the vertical direction Z-Z. The intermediate portion 403 may connect the first end portion 401 and the second end portion 402. Exemplarily, the lower portion 430 may form the first end portion 401. The upper portion 420 and the extender housing 440 may form the intermediate portion 403 and the second end portion 402. The first end portion 401 may engage the tower portion 230. The intermediate portion 403 may be provided with an opening 426. The latch 600 may pass through the opening 426 to lock a card such as the standard add-in card 912 or the tall add-in card 911. With this configuration, the latch 600 can easily lock the add-in card inserted into the first card slot 210. Exemplarily, when the latch 600 is in the locked position, it may pass through the extender 400 so as to lock the add-in card. For example, the rib 630 of the latch 600 may be configured to pass through the extender 400 for locking a card such as the standard add-in card 912 or the tall add-in card 911. Exemplarily, the opening 426 may be provided in the end portion 423. The opening 426 may be disposed above the bar 425 of the end portion 423. In order to be able to pass through the opening 426, in the transverse direction X-X, the rib 630 may be narrower than the rib of the standard connector.

Exemplarily, in the longitudinal direction X-X, the second end portion 402 may protrude outwardly from the intermediate portion 403. The second end portion 402 is disposed above the latch 600 and protrudes outwardly from the intermediate portion 403 in the longitudinal direction X-X, such that the space above the latch 600 can be utilized to enable more space therein for the enlarged tower extension member 400. Such a configuration may enable the extender 400 to have enough mechanical strength. As described above, in the extender 400, the end portion 423 of the upper portion 420 may include the bar 425 against which the latch 600 can abut when the latch 600 is in the locked position. The bar 425 may not be embedded the extender housing 440. The second end portion 402 may include the extender housing 440, such that the second end portion 402 can protrude outwardly in the longitudinal direction X-X from the intermediate portion 403. In this way, the end portion 423 of the extender body 410 may be flat and straight, without bents, such that the extender body 410 can be processed simply. Optionally, a bend may be provided on the end portion 423 by, for example, having the upper portion of the end portion 423 bent outward in the longitudinal direction X-X with respect to its lower portion.

The inventors have recognized and appreciated that when a tall add-in card is inserted into a standard electrical connector (such as those configured according to DDR5 or below standards provided by JEDEC), the tall add-in card may be taller (e.g., twice taller) than the electrical connector in a vertical direction. The electrical connector may provide fixation and protection for the lower portion of the tall add-in card within a limited range. The portion of the tall add-in card extends beyond the standard electrical connector may not be sufficiently supported. When a system comprising the electrical connector vibrates during use, the upper portion of the tall add-in card may waggle significantly, which may result in the electrical connector being susceptible to damage and affect the stability of the signal transmission.

According to aspects of the present disclosure, an electrical connector may have an extender connected to a tower portion of a housing, such that the extender and the tower portion included in the housing can together form a tower of the electrical connector. In this way, the vertical height of the tower of the electrical connector can be significantly higher, thereby providing more adequate fixation and protection for both sides of the tall add-in card. Accordingly, the waggle of the tall add-in card can be decreased, the stability of the signal transmission can be improved, and the housing is protected from damage caused by the waggle of the tall add-in card. Optionally, the longitudinal length and the transverse width of the electrical connector can both comply with industry standards such as JEDEC standards.

According to aspects of the present disclosure, a latch of the electrical connector may be positioned in the vertical direction to be adapted to the standard add-in card inserted into the electrical connector. A component, such as a notch, on each side of the tall add-in card for locking with the latch may be similar to the standard add-in card, such that the latch is adapted to both the standard add-in card and the tall add-in card. In this way, the electrical connector can be compatible with both the standard add-in card and the tall add-in card. A user may install a desired add-in card onto the electrical connector as needed. Optionally, the latch of the electrical connector may be disposed at the tower portion. In this way, when the electrical connector is used for connecting with only the standard add-in card, it is selectable that the extender is not installed, thereby reducing costs. Optionally, when the extender is connected, the latch may pass through the extender to lock the add-in card inserted into the electrical connector. The latch may abut against the extender, when in a locked position, thereby providing certain fixation for the extender.

According to aspects of the present disclosure, the extender on the electrical connector may have an enough length in an insertion direction of the add-in card, enabling the extender to connect to a circuit board to which the electrical connector is attached. In this way, the connection strength of the extender to the tower portion can be increased to ensure that the extender can be securely fixed to the tower portion. When the extender is connected to the circuit board, the housing may be clamped between the extender and the circuit board.

According to aspects of the present disclosure, the extender may comprise an extender body and an extender housing. The extender body may include an upper portion and a lower portion that are connected to each other. The lower portion may engage the tower portion of the housing. The upper portion may be disposed higher than the tower portion in the vertical direction. The extender housing may wrap around the upper portion. The extender housing may be disposed outside the tower portion. The extender can be connected to the tower portion of the housing by the extender body. The extender housing may provide protection for the extender body. Optionally, the extender may comprise a material with greater mechanical strength, such as metal. The extender may extend beyond the housing to be connected to the circuit board, thereby ensuring the connection strength between the extender and the circuit board. Optionally, the extender housing may be formed onto the extender body by, for example, overmolding. Exemplarily, a part of the extender body disposed above the tower portion may be disposed in the extender housing. Optionally, the extender housing may be made of insulating materials to avoid electrical connection of the extender body with circuits in the add-in card.

According to aspects of the present disclosure, the extender body may have parts disposed on opposite sides of a card slot. The card slot extends in a longitudinal direction and is formed in the housing, and an end of the card slot may extend into the tower portion. The aforementioned “opposite sides of a card slot” may refer to the opposite sides of the card slot in the transverse direction. During use, the add-in card may waggle in the transverse direction prominently, which is determined by the shapes of the add-in card and the electrical connector. The extender body including the parts disposed on opposite sides of the card slot may be configured to strengthen the housing in the transverse direction, preventing the housing from damage when the add-in card waggles in the transverse direction.

Having thus described several aspects of embodiments of card edges connectors, it is to be appreciated that various alterations, modifications, and improvements will readily occur to those skilled in the art. Such alterations, modifications, and improvements are intended to be part of this disclosure, and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

For example, although many inventive aspects are shown and described with reference to a card edge connector having a vertical configuration, it should be appreciated that aspects of the present disclosure is not limited in this regard, as any of the inventive concepts, whether alone or in combination with one or more other inventive concepts, may be used in other types of electrical connectors, such as backplane connectors, daughter card connectors, cable connectors, stacking connectors, mezzanine connectors, I/O connectors, chip sockets, Gen Z connectors, right angle connectors, coplanar connectors etc.

As another example, although mounting tails were illustrated as surface mounting elements, other configurations may also be used, such as press fit “eye of the needle” compliant sections that are designed to fit within vias of printed circuit boards, spring contacts, solderable pins, etc., as aspects of the present disclosure are not limited to the use of any particular mechanism for attaching connectors to printed circuit boards.

In the description of the present disclosure, it is to be understood that orientation or positional relationships indicated by orientation words “front”, “rear”, “upper”, “lower”, “left”, “right”, “transverse direction”, “vertical direction”, “perpendicular”, “horizontal”, “top”, “bottom” and the like usually are shown based on the accompanying drawings, only for the purposes of the case in describing the present disclosure and simplification of its descriptions. Unless stated to the contrary, these orientation words do not indicate or imply that the specified apparatus or element has to be specifically located, and structured and operated in a specific direction, and therefore, should not be understood as limitations to the present disclosure. The orientation words “inside” and “outside” refer to the inside and outside relative to the contour of each component itself.

For facilitating description, the spatial relative terms such as “on”, “above”, “on an upper surface of” and “upper” may be used here to describe a spatial position relationship between one or more components or features and other components or features shown in the accompanying drawings. It should be understood that the spatial relative terms not only include the orientations of the components shown in the accompanying drawings, but also include different orientations in use or operation. For example, if the component in the accompanying drawings is turned upside down completely, the component “above other components or features” or “on other components or features” will include the case where the component is “below other components or features” or “under other components or features”. Thus, the exemplary term “above” can encompass both the orientations of “above” and “below”. In addition, these components or features may be otherwise oriented (for example rotated by 90 degrees or other angles) and the present disclosure is intended to include all these cases.

The present disclosure is not limited to the details of construction or the arrangements of components set forth in the foregoing description and/or the drawings. Various embodiments are provided solely for purposes of illustration, and the concepts described herein are capable of being practiced or carried out in other ways. Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

In the claims, as well as in the specification above, use of ordinal terms such as “first,” “second,” “third,” etc. does not by itself connote any priority, precedence, or order of one element over another or the temporal order in which acts of a method are performed, but are used merely as labels to distinguish one element having a certain name from another element having a same name (but for use of the ordinal term) to distinguish the elements.

What is claimed is:

1. A memory card connector comprising:
a housing comprising a body extending in a longitudinal direction and having an end, a tower portion extending from the end of the body in a vertical direction perpendicular to the longitudinal direction, and a slot extending from the body to the tower portion; and
a plurality of conductive elements held in the housing, each of the plurality of conductive elements comprising a mating contact portion curving into the slot and a tail portion extending out of a mounting face of the housing,
wherein the tower portion of the housing comprises a groove extending in the vertical direction and beyond the mounting face.

2. The connector of claim 1, wherein:
the groove is a first groove disposed on a side of the slot;
the tower portion of the housing comprises a second groove facing away from the slot; and
the connector comprises a latch at least partially disposed in the second groove and movably coupled to the tower portion between a locked position and unlocked position.

3. The connector of claim 2, wherein:
the latch comprises a handle disposed outside the second groove and extending outwardly from the tower portion, and a rib extending from the handle in an opposite direction; and
the rib is narrower than the handle in a transverse direction perpendicular to both the longitudinal direction and the vertical direction.

4. The connector of claim 1, comprising:
an extender comprising a first portion extending through the groove of the tower portion and a second portion disposed on the tower portion.

5. The connector of claim 4, wherein:
the second portion of the extender comprises a slot aligned with a portion of the slot of the housing that extends in the tower portion.

6. The connector of claim 5, wherein:
the extender comprises a protrusion protruding into the slot.

7. The connector of claim 4, wherein the extender comprises:
an insulative housing; and
a conductive body comprising an upper portion disposed in the extender housing and a lower portion extending out of the insulative housing and through the groove of the tower portion.

8. The connector of claim 7, wherein:
the lower portion of the conductive body of the extender comprises a barb engaging the tower portion inside the groove.

9. The connector of claim 7, wherein:
the lower portion of the conductive body of the extender is configured to insert into a hole of a circuit board; and
the tail portions of the plurality of conductive elements are configured to surface mount to the circuit board.

10. An electrical connector comprising:
a housing comprising a body having a mating face and a mounting face, and a tower extending from an end of the body and beyond the mating face of the body of the housing; and
a latch movably coupled to the housing between a locked position and an unlocked position and comprising a rib configured to extend through an opening of the tower at the locked position.

11. The electrical connector of claim 10, wherein the tower comprises:
a tower portion extending from the end of the body; and
an extender at least partially disposed on the tower portion and comprising the opening.

12. The electrical connector of claim 11, wherein:
the housing comprises a slot extending from the body to the tower;
the tower portion of the tower comprises a groove disposed on a side of the slot; and
the extender of the tower comprises a first portion extending through the groove and a second portion disposed on the groove.

13. The electrical connector of claim 12, wherein:
the second portion of the extender comprises a first sidewall and a second sidewall on opposite sides of the slot, first protrusions extending from the first sidewall into the slot, and second protrusions extending from the second sidewall into the slot; and
the first protrusions and the second protrusions are staggered.

14. The electrical connector of claim 12, wherein the extender comprises:
a conductive body having a lower portion extending through the groove and an upper portion disposed above the tower portion; and
an insulative housing at least partially enclosing the upper portion of the conductive body.

15. The electrical connector of claim 14, wherein the conductive body comprises:
a first side portion extending from the upper portion to the lower portion;
a second side portion extending from the upper portion to the lower portion; and
an end portion joining the first side portion and the second side portion at the upper portion.

16. The electrical connector of claim 15, wherein:
the first and second side portions are either embedded in the insulative housing of the extender or disposed inside the tower portion.

17. The electrical connector of claim 10, wherein:
the body is elongated in a longitudinal direction;
the tower is elongated in a vertical direction perpendicular to the longitudinal direction; and
the tower is not wider than the body in a transverse direction perpendicular to both the longitudinal direction and the vertical direction.

18. A method of manufacturing a memory card connector comprising:
providing a housing comprising a body having a mating face and a mounting face, a tower portion extending from an end of the body and having a groove extending beyond the mounting face of the body, and a slot recessed from the mating face of the body and extending into the tower portion;
providing an extender comprising a first portion and a second portion; and
inserting the second portion of the extender into the groove of the housing.

19. The method of claim 18, comprising:
assembling a latch to the tower portion of the housing, wherein at a locked position the latch extends above the tower portion and below the extender.

20. The method of claim 18, wherein:
providing the extender comprises overmolding an insulative material over a portion of a conductive body to form the first portion.
